(19) United States
(12) Patent Application Publication
(10) Pub. No.: US 2026/0230072 A1
(43) Pub. Date: Aug. 6, 2026

(54) GATE DRIVER CIRCUITS WITH PROGRAMMABLE PERFORMANCE CHARACTERISTICS

(71) Applicant: ABB Schweiz AG, Baden (CH)

(72) Inventor: Kalyan Gokhale, New Berlin, WI (US)

(21) Appl. No.: 19/044,526

(22) Filed: Feb. 3, 2025

(51) Int. Cl. H03K 17/567

(52) U.S. Cl. CPC H03K 17/567

(57) ABSTRACT

In one embodiment a gate driver circuit is provided. The gate driver circuit includes a turn-on circuit path and a turn-off circuit path. The turn-on circuit path is coupled between a gate of a solid-state switch and a first output of a gate driver, and the turn-on circuit path defines a turn-on time for the solid-state switch. The turn-off circuit path is coupled between the gate and a second output of the gate driver, and the turn-off circuit path defines a turn-off time for the solid-state switch. The turn-on circuit path and/or the turn-off circuit path includes one or more branches of resistors and fuses connected in series, where the one or more branches are electrically coupled in parallel.

### BACKGROUND

The field of the disclosure relates to solid-state switches, and more particularly, to controlling turn-on and turn-off times of solid-state switches.

Gate drive circuits that drive Insulated Gate Bipolar Transistors (IGBTs), Metal-Oxide Semiconductor Field-Effect Transistors (MOSFETs), or other types of gate-controlled solid-state switches commonly utilize two resistors (Ron and Roff) that control the turn-on and turn-off behavior of the solid-state switches. Ron and Roff values are selected to match the specific device characteristics, such as a voltage rating, a current rating, switching losses, conducted and radiated emission requirements, and device technology that is specific to the supplier of the solid-state switch. As many different types of gate-controlled solid-state switches may be in use, the result is a proliferation of gate drive circuits with different values of Ron and Roff, even across the same product, due to substitution of different gate-controlled devices over time, which is undesirable.

Thus, it is desirable to improve on gate drive circuits for solid-state switches, in order to provide flexibility in modifying Ron and Roff for solid-state switches.

### BRIEF DESCRIPTION

In one embodiment a gate driver circuit is provided. The gate driver circuit includes a turn-on circuit path and a turn-off circuit path. The turn-on circuit path is coupled between a gate of a solid-state switch and a first output of a gate driver, and the turn-on circuit path defines a turn-on time for the solid-state switch. The turn-off circuit path is coupled between the gate and a second output of the gate driver, and the turn-off circuit path defines a turn-off time for the solid-state switch. The turn-on circuit path and/or the turn-off circuit path includes one or more branches of resistors and fuses connected in series, where the one or more branches are electrically coupled in parallel.

In another embodiment, a gate driver circuit is provided. The gate driver circuit includes a first circuit path and a second circuit path. The first circuit path is coupled between a node and an output of a gate driver. The second circuit path is coupled between the node and a gate of a solid-state switch. The first circuit path and/or the second circuit path includes one or more branches of resistors and fuses connected in series, where the one or more branches are electrically coupled in parallel.

In another embodiment, a gate driver circuit is provided. The gate driver circuit includes a turn-on circuit path coupled between a gate of a solid-state switch and a first output of a gate driver, where the turn-on circuit path defines a turn-on time for the solid-state switch, where the turn-on circuit path includes a plurality of branches of resistors and fuses connected in series, and where the turn-on time is configurable based on which of the fuses in the plurality of branches are selectively blown open.

Various refinements exist of the features noted in relation to the above-mentioned aspects and embodiments. Further features may also be incorporated in the above-mentioned aspects and embodiments as well. These refinements and additional features may exist individually or in any combination. For instance, various features discussed below in relation to any of the illustrated examples may be incorporated into any of the above-described aspects and embodiments, alone or in any combination.

### BRIEF DESCRIPTION OF DRAWINGS

These and other features, aspects, and advantages of the present disclosure will become better understood when the following detailed description is read with reference to the accompanying drawings in which like characters represent like parts throughout the drawings.

FIG. 1 depicts a known power conversion unit for driving a motor.

FIG. 2 depicts a known gate drive circuit for driving a solid-state switch.

FIG. 3 depicts a known variation of the gate drive circuit of FIG. 2.

FIG. 4 depicts a gate driver circuit in an exemplary embodiment.

FIG. 5 depicts gate diver circuit in another exemplary embodiment

FIG. 6 depicts a gate driver circuit in another exemplary embodiment.

FIG. 7 depicts gate diver circuit in another exemplary embodiment.

FIG. 8 depicts a gate driver circuit in another exemplary embodiment.

Unless otherwise indicated, the drawings provided herein are meant to illustrate features of embodiments of this disclosure. These features are believed to be applicable in a wide variety of systems comprising one or more embodiments of this disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

Electrical power conversion circuits, such as inverters, uninterruptable power supplies (UPS), and direct current (DC) to DC (DC-DC) converters utilize power devices or power switches such as IGBTs, MOSFETs, or other types of solid-state switches for power conversion.

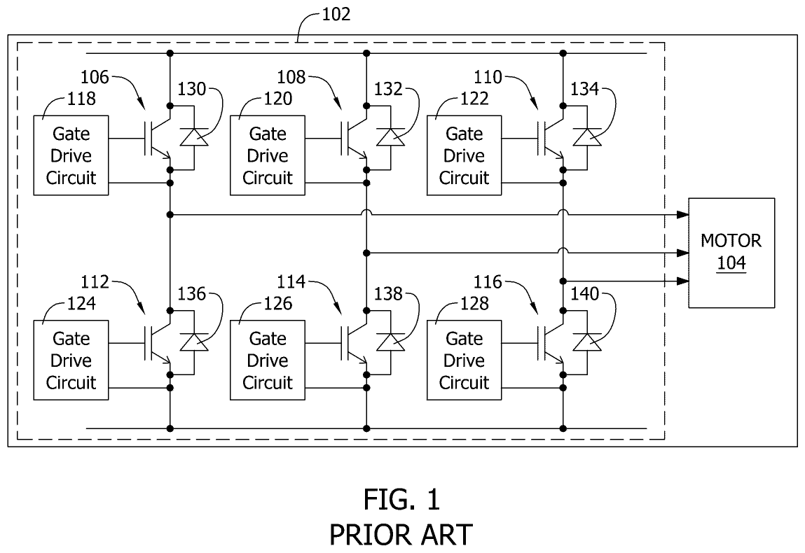

FIG. 1 depicts a known power conversion unit 102 for driving a motor 104. In FIG. 1, power conversion unit 102 is a three-phase inverter that utilizes six IGBTs 106, 108, 110, 112, 114, 116, each controlled by a respective gate drive circuit 118, 120, 122, 124, 126, 128. Gate drive circuits 118, 120, 122, 124, 126, 128 turn on and turn off their respective IGBTs 106, 108, 110, 112, 114, 116 by controlling their gate voltage. For example, gate drive circuits 118, 120, 122, 124, 126, 128 may apply +15 volts (V) to turn on their respective IGBTs 106, 108, 110, 112, 114, 116 and apply −7 V to turn off and keep off their respective IGBTs 106, 108, 110, 112, 114, 116. In this embodiment, free-wheeling diodes 130, 132, 134, 136, 138, 140 are in parallel with IGBTs 106, 108, 110, 112, 114, 116, respectively.

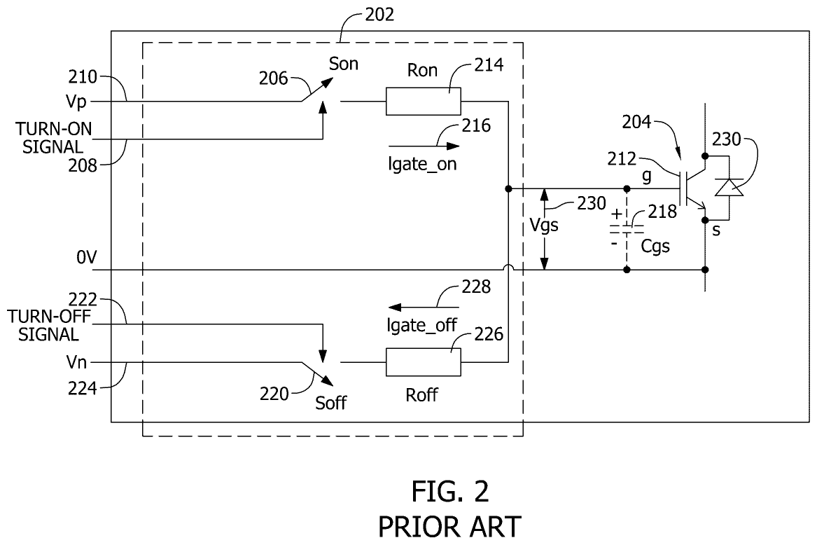

FIG. 2 depicts a known gate drive circuit 202 for driving a solid-state switch 204. An electronic switch Son 206, in response to receiving a turn-on signal 208, applies a positive voltage (Vp) 210 to a gate 212 of an solid-state switch 204 via a resistor Ron 214 to turn on solid-state switch 204 (utilizing a gate current (igate_on) 216 which charges a gate capacitance (Cgs) 218 of solid-state switch 204 towards Vp 210). Another electronic switch Soff 220, in response to receiving a turn-off signal 222, applies a negative voltage (Vn) 224 to gate 212 of solid-state switch 204 via a resistor Roff 226 to turn off solid-state switch 204 (utilizing a gate current (igate_off) 228 which charges Cgs 218 of solid-state switch 204 towards Vn 224). In this embodiment, a free-wheeling diode 232 is in parallel with solid-state switch 204.

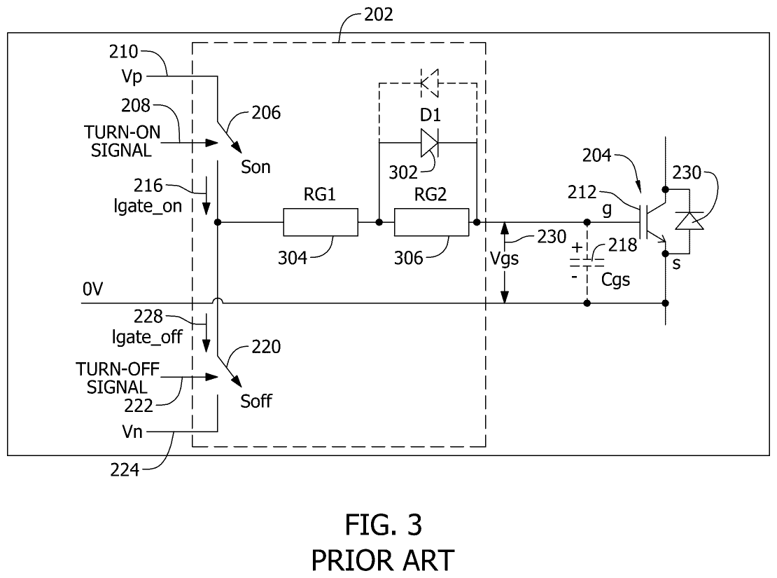

A variation of FIG. 2 is depicted in FIG. 3. With a polarity of diode 302 (denoted D1) as shown, the effective resistance value of Ron 214=the resistance of resistor 304 (denoted RG1), and the effective resistance value of Roff 226=the resistance of resistor 304+the resistance of resistor 306 (denoted RG2). The resistance value of Ron 214 is less than the resistance value of Roff 226. If the polarity of diode 302 is reversed as shown as a dotted outline, then the effective resistance value of Ron 214=the resistance value of resistor 304+the resistance value of resistor 306, and the effective resistance value of Roff 226=the resistance value of resistor 304. Both the circuit shown in FIGS. 1 and 2 can be designed such that they produce an equivalent electrical behavior.

Referring back to FIG. 2, Cgs 218 represents a non-linear capacitive load to gate drive circuit 202, which is charged to Vp 210 during the turn-on event. Igate_on 216 designates the current during turn-on to charge Cgs 218 to Vp 210. The rate at which Cgs 218 is charged or a gate-to-source (Vgs) 232 rises towards the on-state voltage of Vp 210 determines how fast solid-state switch 204 turns on, and it is primarily a function of Ron 214. A higher resistance value of Ron 214 results in a lower value of igate_on 216 and a slower rate of rise of Vgs 232. Therefore, the turn-on time of solid-state switch 204 is longer as the resistance value of Ron 214 increases.

Similarly, igate_off 228 designates the current during turn-off to charge Cgs 218 to Vn 224. The resistance value of Roff 226 determines how fast Vgs 232 charges towards the off-state voltage of Vn 224 and therefore, it affects the turn-off speed of solid-state switch switch 204. A higher resistance value of Roff 226 results in a lower value of igate_off 228 and a slower rate of fall of Vgs 232 towards Vn 224. Therefore, the turn-off time of solid-state switch 204 is longer as the resistance value of Roff 226 increases.

Because of the finite durations of turn-on and turn-off times of solid-state switch 204 switching events, there is an energy loss in solid-state switch 204 at every turn-on and turn-off event. A higher resistance value of Ron 214 (or Roff 226) results in a longer turn-on (or turn-off) time and therefore, the turn-on (or turn-off) event losses are higher. Lower resistance values of Ron 214 and Roff 226 are desired to reduce the power loss in solid-state switch 204 during the switching events. However, faster turn-on and turn-off times may result in higher conducted and radiated emissions, which are also undesirable.

Generally, gate drive circuit 202 of FIG. 2 can provide independent control of the turn-on and the turn-off time for solid-state switch 204. If independent control is not needed, then gate drive circuit 202 of FIG. 3 may be used without diode 302 and resistors 304, 306 may utilize a single resistor. Further, although diode 302 is depicted in gate drive circuit 202 as being electrically coupled in parallel with resistor 306, diode 302 may be electrically coupled in parallel with resistor 304.

As discussed briefly above, a variety of gate-controlled devices, with different current and voltage ratings from different suppliers, may be used to design and produce a family of converts that vary depending on the different requirements of the loads of the converts. For example, for inverters, different gate-controlled devices may be used that vary depending on the power ratings and voltages of the motors being driven by the inverters. This presents a problem of designing, producing, and maintaining a wide variety and number of gate drive circuit designs with different combinations of Ron 214 and Roff 226 resistance values that are selected for a specific version of solid-state switch 204, Cgs 218, and the switching characteristics of solid-state switch 204, along with providing acceptable levels of switching losses, conducted emissions, and radiated emissions.

The embodiments described herein address these and other shortcomings of typical gate drive circuits, such as gate drive circuit 202, utilizing circuits that can generate different combinations of independent Ron and Roff values utilizing fuses that are selectively blown. The different combinations of independent Ron and Roff values correspond to different configurations of turn-on and turn-off times. respectively.

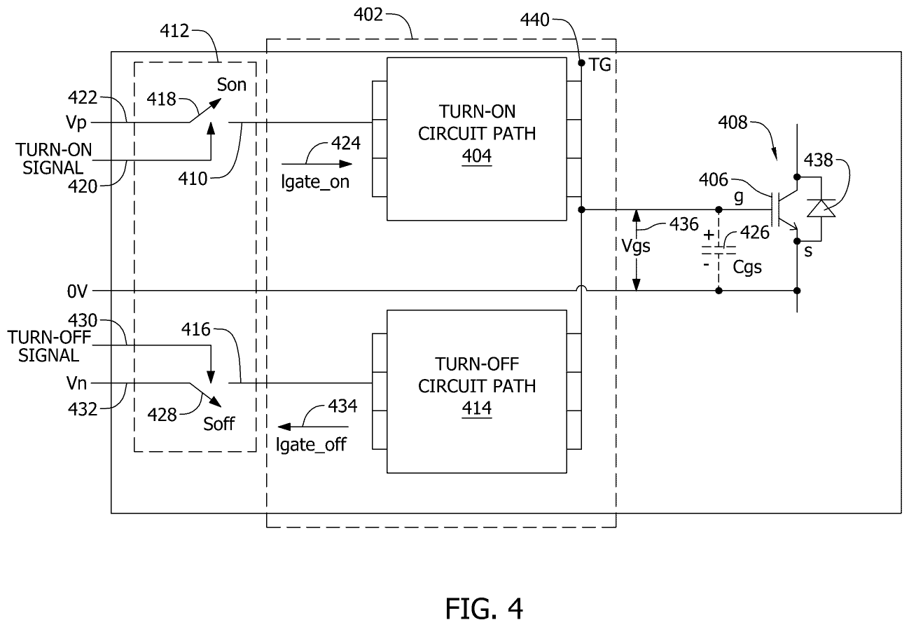

FIG. 4 depicts a gate driver circuit 402 in an exemplary embodiment. In this embodiment, gate driver circuit 402 includes a turn-on circuit path 404 coupled between a gate 406 of a solid-state switch 408 and a first output 410 of a gate driver 412. Solid-state switch 408 may include IGBTs, MOSFETs, or other types of gate-controlled devices. In FIG. 4, turn-on circuit path 404 defines a turn-on time for solid-state switch 408 (e.g., turn-on circuit path 404 defines Ron for solid-state switch 408).

In this embodiment, gate driver circuit 402 further includes a turn-off circuit path 414 coupled between gate 406 of a solid-state switch 408 and a second output 416 of gate driver 412. In FIG. 4, turn-off circuit path 414 defines a turn-off time for solid-state switch 408 (e.g., turn-off circuit path 414 defines Roff for solid-state switch 408).

In this embodiment, turn-on circuit path 404 and/or turn-off circuit path 414 includes one or more branches of resistors and fuses connected in series (not shown), where the one or more branches are electrically coupled in parallel. The fuses in turn-on circuit path 404 and/or turn-off circuit path 414 may be selectively blown open, which generates different values for Ron and/or Roff, respectively. This will be discussed later.

An electronic switch Son 418, in response to receiving a turn-on signal 420, applies a positive voltage (Vp) 422 to gate 406 of solid-state switch 408 via the effective Ron associated with turn-on circuit path 404 to turn on solid-state switch 408 (utilizing a gate current (igate_on) 424, which charges a gate capacitance (Cgs) 426 of solid-state switch 408 towards Vp 422). Another electronic switch Soff 428, in response to receiving a turn-off signal 430, applies a negative voltage (Vn) 432 to gate 406 of solid-state switch 408 via the effective Roff associated with turn-off circuit path 414 to turn off solid-state switch 408 (utilizing a gate current (igate_off) 434 which charges Cgs 426 of solid-state switch 408 towards Vn 432).

Cgs 426 represents a non-linear capacitive load to gate driver 412, which is charged to Vp 422 during the turn-on event. Igate_on 424 designates the current during turn-on to charge Cgs 426 to Vp 422. The rate at which Cgs 426 is charged or a gate-to-source voltage (Vgs) 436 rises towards the on-state voltage of Vp 422 determines how fast solid-state switch 408 turns on, and it is primarily a function of the effective Ron associated with turn-on circuit path 404. A higher resistance value of turn-on circuit path 404 results in a lower value of igate_on 424 and a slower rate of rise of Vgs 436. Therefore, the turn-on time of solid-state switch 408 is longer as the effective Ron resistance value turn-on circuit path 404 increases.

Similarly, igate_off 434 designates the current during turn-off to charge Cgs 426 to Vn 432. The effective Roff resistance value of turn-off circuit path 414 determines how fast Vgs 436 charges towards the off-state voltage of Vn 432 and therefore, it affects the turn-off speed of solid-state switch 408. A higher effective Roff resistance value associated with turn-off circuit path 414 results in a lower value of igate_off 434 and a slower rate of fall of Vgs 436 towards Vn 432. Therefore, the turn-off time of solid-state switch 408 is longer as the effective resistance value of turn-off circuit path 414 increases.

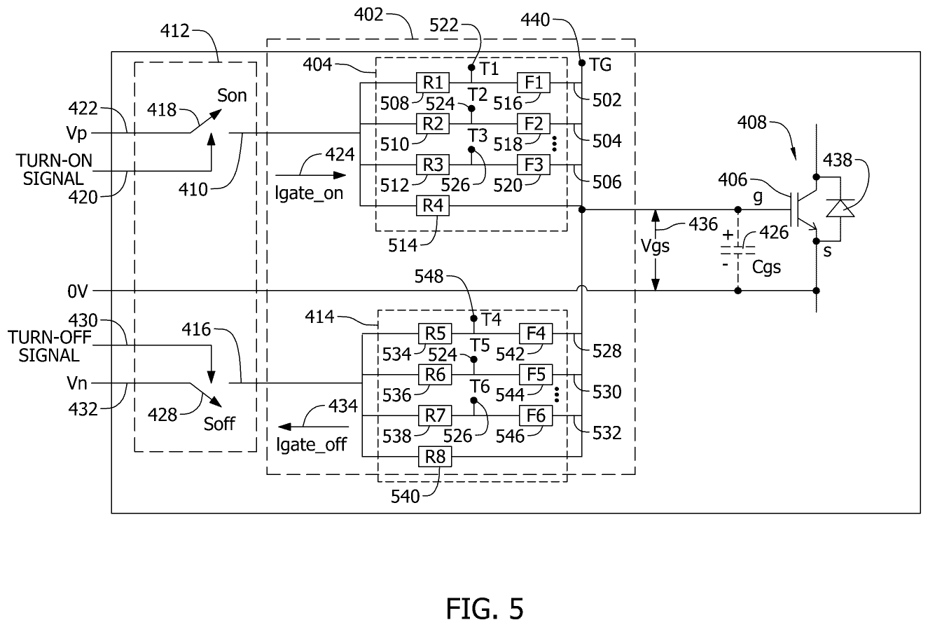

In this embodiment, a free-wheeling diode 438 is electrically coupled across solid-state switch 408, although free-wheeling diode 438 may be omitted in other embodiments. Further, in this embodiment, gate driver circuit 402 includes electrical terminal 440 (denoted as TG), which will be discussed with respect to FIG. 5.

FIG. 5 depicts gate driver circuit 402 in another exemplary embodiment. In this embodiment, turn-on circuit path 404 includes a plurality of branches 502, 504, 506 of resistors 508, 510, 512 (denoted R1, R2, and R3, respectively) and fuses 516, 518, 520 (denoted F1, F2, and F3, respectively) connected in series. Branches 502, 504, 506 are coupled in parallel between first output 410 of gate driver 412 and gate 406 of solid-state switch 408. In this embodiment, branch 502 is formed by resistor 508 in series with fuse 516, branch 504 is formed by resistor 510 in series with fuse 518, and branch 506 is formed by resistor 512 in series with fuse 520. In this embodiment, a resistor 514 (denoted R4) is in parallel with branches 502, 504, 506, although resistor 514 may be omitted in other embodiments. Further, turn-on circuit path 404 may include fewer or more branches 502, 504, 506 in other embodiments. In this embodiment, branches 502, 504, 506 include respective electrical terminals 522, 524, 526 (denoted T1, T2, and T3, respectively). Electrical terminal 522 is electrically coupled between resistor 508 and fuse 516, electrical terminal 524 is electrically coupled between resistor 510 and fuse 518, and electrical terminal 526 is electrically coupled between resistor 512 and fuse 520. Electrical terminals 522, 524, 526 may be used in combination with electrical terminal 440 to selectively blow open one or more of fuses 516, 518, 520 to vary Ron.

In this embodiment, turn-off circuit path 414 includes a plurality of branches 528, 530, 532 of resistors 534, 536, 538 (denoted R5, R6, and R7, respectively) and fuses 542, 544, 546 (denoted F4, F5, and F6, respectively) connected in series. Branches 528, 530, 532 are coupled in parallel between second output 416 of gate driver 412 and gate 406 of solid-state switch 408. In this embodiment, branch 528 is formed by resistor 534 in series with fuse 542, branch 530 is formed by resistor 536 in series with fuse 544, and branch 532 is formed by resistor 538 in series with fuse 546. In this embodiment, a resistor 540 (denoted R8) is in parallel with branches 528, 530, 532, although resistor 540 may be omitted in other embodiments. Further, turn-off circuit path 414 may include fewer or more branches 528, 530, 532 in other embodiments. In this embodiment, branches 528, 530, 532 include respective electrical terminals 548, 550, 552 (denoted T4, T5, and T6, respectively). Electrical terminal 548 is electrically coupled between resistor 534 and fuse 542, electrical terminal 550 is electrically coupled between resistor 536 and fuse 544, and electrical terminal 552 is electrically coupled between resistor 538 and fuse 546. Electrical terminals 548, 550, 552 may be used in combination with electrical terminal 440 to selectively blow open one or more of fuses 542, 544, 546 to vary Roff. Generally, the resistance values of resistors 508, 510, 512, 514 for turn-on circuit path 404 are independently selectable values and may be different than the resistance values of resistors 534, 536, 538, 540 of turn-off circuit path 414.

In FIG. 5, the effective Ron of turn-on circuit path 404 is the parallel combination of branches 502, 504, 506 and resistor 514. Further, the effective Roff of turn-off circuit path 414 is the parallel combination of branches 528, 530, 532 and resistor 540.

In the embodiment illustrated in FIG. 5, six fuses 516, 518, 520, 542, 544, 546 are present. Depending on which of fuses 516, 518, 520, 542, 544, 546 are blown open, eight different resistance values for turn-on circuit path 404 and turn-off circuit path 414 may be achieved. Depending on which of fuses 516, 518, 520 are selectively blown open, Ron, which is the effective resistance of turn-on circuit path 404, may be modified, which allows the turn-on time for solid-state switch 408 to be configurable. Similarly, depending on which of fuses 542, 544, 546 are selectively blown open, Roff, which is the effective resistance of turn-off circuit path 414, may be modified, which allows the turn-off time for solid-state switch 408 to be configurable.

For example, in a production environment, a printed circuit board (PCB) may be assembled based on FIG. 5 to initially include six fuses 516, 518, 520, 542, 544, 546. As an example, assume that resistors 508, 510, 512, 514 are loaded onto the PCB and have values of four ohms, six ohms, eight ohms, and ten ohms, respectively. If fuses 516, 518, 520 electrically conduct (i.e., fuses 516, 518, 520 are not blown open), then the effective resistance value of Ron, and turn-on circuit path 404, would be 1.558 ohms. If fuses 516, 518, 520 are not electrically conductive (i.e., fuses 516, 518, 520 are blown open), then the effective resistance Ron of turn-on circuit path 404 is defined by resistor 514, or ten ohms.

Depending on which of fuses 516, 518, 520 are blown open, eight different values for turn-on circuit path 404 may be achieved. In the example above, the eight possible values for the effective resistance of turn-on circuit path 404 would be 1.558 ohms, 1.935 ohms, 2.105 ohms, 2.553 ohms, 2.875 ohms, 3.75 ohms, 4.444 ohms, and 10 ohms, thereby providing a configurable turn-on time for solid-state switch 408 that varies based on which of fuses 516, 518, 520 are blown open.

Similar functionality may also apply for Roff, the effective resistance of turn-off circuit path 414. As an example, assume that resistors 534, 536, 538, 540 are loaded onto the PCB and have values of four ohms, six ohms, eight ohms, and ten ohms, respectively. If fuses 542, 544, 546 electrically conduct (i.e., fuses 542, 544, 546 are not blown open), then the effective resistance value of Roff and turn-off circuit path 414, would be 1.558 ohms. If fuses 542, 544, 546 are not electrically conductive (i.e., fuses 542, 544, 546 are blown open), then the effective resistance of turn-off circuit path 414 is defined by resistor 540, or ten ohms.

Depending on which of fuses 542, 544, 546 are blown open, eight different values for turn-off circuit path 414 may be achieved. In the example above, the eight possible values for the effective resistance Roff of turn-off circuit path 414 would be 1.558 ohms, 1.935 ohms, 2.105 ohms, 2.553 ohms, 2.875 ohms, 3.75 ohms, 4.444 ohms, and 10 ohms, thereby providing a configurable turn-off time for solid-state switch 408 that varies based on which of fuses 542, 544, 546 are blown open.

Although the example above describes the same eight possible values for the effective resistance Ron of turn-on circuit path 404 and Roff of turn-off circuit path 414, other values of resistors 508, 510, 512, 514, 534, 536, 538, 540 may be used such that the achievable values for the effective resistance Ron of turn-on circuit path 404 and Roff of turn-off circuit path 414 are different. Further, turn-on circuit path 404 and/or turn-off circuit path 414 may have a different number of branches 502, 504, 506, 528, 530, 532, resulting in more than eight possible values for the effective resistance Ron of turn-on circuit path 404 and Roff of turn-off circuit path 414 (and consequentially, resulting in more than eight possible configurations for turn-on time and/or turn-off time for solid-state switch 408).

In a production environment, fuses 516, 518, 520, 542, 544, 546 may be selectively blown open using a programming current pulse applied between electrical terminal 440 and electrical terminals 522, 524, 526, 548, 550, 552. The programming current pulse may, for example be a current pulse selectively applied across fuses 516, 518, 520, 542, 544, 546 in order to selectively blow open fuses 516, 518, 520, 542, 544, 546.

One advantage of gate driver circuit 402 is that, in combination with a programming procedure, an increased manufacturing and procurement efficiency is achieved by stocking a PCB that utilizes gate driver circuit 402, with fuses 516, 518, 520, 542, 544, 546, that provides (in one embodiment) eight independent Ron and Roff values using six fuses 516, 518, 520, 542, 544, 546. When needed (e.g., just in time), such a PCB is programmed or selected for the desired effective values of Ron, associated with turn-on circuit path 404, and Roff, associated with turn-off circuit path 414, by clearing, opening, or blowing open, the appropriate fuses 516, 518, 520, 542, 544, 546. The resulting resistance values for Ron and Roff may more effectively suite a specific type of gate-controlled device that is being used. Fuses 516, 518, 520, 542, 544, 546 may be small surface mount devices that have of a low cost, thereby adding a negligible additional cost associated with producing a PCB that utilizes gate driver circuit 402.

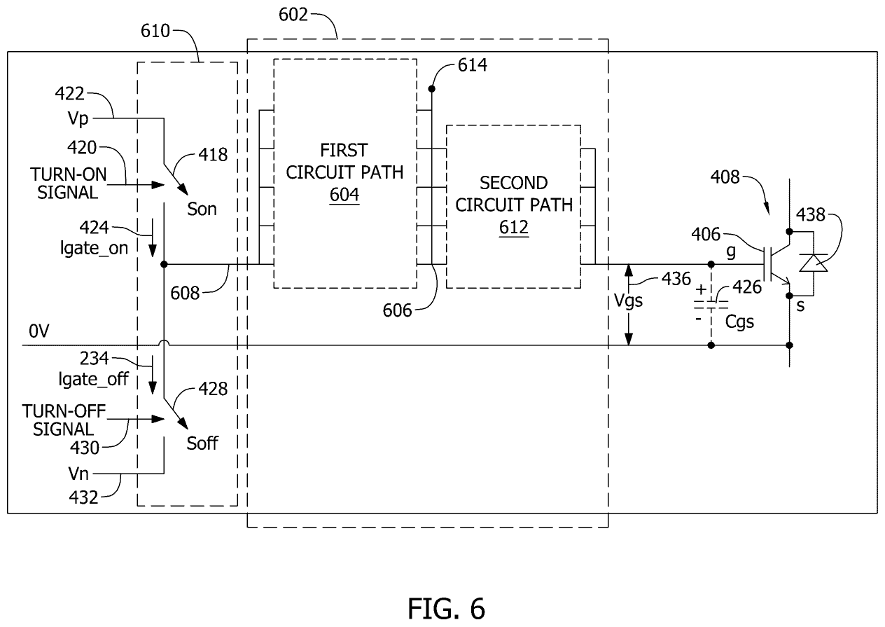

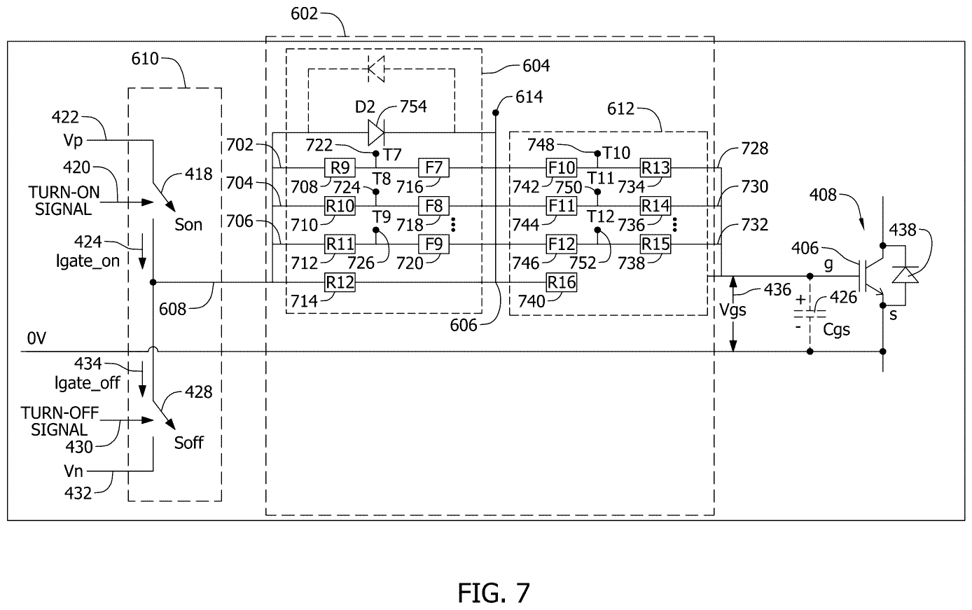

FIG. 6 depicts a gate driver circuit 602 in another exemplary embodiment. In this embodiment, gate driver circuit 602 includes a first circuit path 604 coupled between a node 606 and an output 608 of a gate driver 610, and a second circuit path 612 coupled between node 606 and gate 406 of solid-state switch 408. In this embodiment, first circuit path 604 and/or second circuit path 612 include one or more branches of resistors and fuses connected in series (not shown), where the one or more branches are electrically coupled in parallel. In this embodiment, gate driver 610 operates similarly as previously described for gate driver 412 of FIGS. 4 and 5, with first circuit path 604 and/or second circuit path 612 defining Ron and/or Roff for controlling the turn-on time and/or the turn-off time for solid-state switch 408. In this embodiment, gate driver 610 includes one output 608, in contrast to both of first output 410 and second output 416 of gate driver 412 (see FIGS. 4 and 5). In this embodiment, gate driver circuit 602 includes an electrical terminal 614 located a node 606, which will be discussed later with respect to FIG. 7.

Similar to previously described with respect to FIG. 4 and Cgs 426 and igate_on 424, the rate at which Cgs 426 is charged or Vgs 436 rises towards the on-state voltage of Vp 422 determines how fast solid-state switch 408 turns on, and it is primarily a function of the effective Ron associated with the series resistance of first circuit path 604 and/or second circuit path 612, one of which may have its resistance modified by a diode during turn-on of solid-state switch 408. A higher resistance value of associated with the series combination of first circuit path 604 and/or second circuit path 612 results in a lower value of igate_on 424 and a slower rate of rise of Vgs 436. Therefore, the turn-on time of solid-state switch 408 is longer as the effective Ron resistance value of associated with the series combination of first circuit path 604 and/or second circuit path 612 increases.

Similarly, igate_off 434 designates the current during turn-off to charge Cgs 426 to Vn 432. The effective Roff resistance value associated with the series combination of first circuit path 604 and/or second circuit path 612, one of which may have its resistance modified by a diode during turn-off of solid-state switch 408, determines how fast Vgs 436 charges towards the off-state voltage of Vn 432 and therefore, it affects the turn-off speed of solid-state switch 408. A higher effective Roff resistance value associated with the series resistance of first circuit path 604 and/or second circuit path 612 results in a lower value of igate_off 434and a slower rate of fall of Vgs 436 towards Vn 432. Therefore, the turn-off time of solid-state switch 408 is longer as the effective resistance value associated with the series resistance of first circuit path 604 and/or second circuit path 612 increases.

FIG. 7 depicts gate driver circuit 602 in another exemplary embodiment. In this embodiment, first circuit path 604 includes a plurality of branches 702, 704, 706 of resistors 708, 710, 712 (denoted R9, R10, and R11, respectively) and fuses 716, 718, 720 (denoted F7, F8, and F9, respectively) connected in series. Branches 702, 704, 706 are coupled in parallel between output 608 of gate driver 610 and node 606. In this embodiment, branch 702 is formed by resistor 708 in series with fuse 716, branch 704 is formed by resistor 710 in series with fuse 718, and branch 706 is formed by resistor 712 in series with fuse 720. In this embodiment, resistor 714 (denoted R12) is in parallel with branches 702, 704, 706, although resistor 714 may be omitted in other embodiments. Further, first circuit path 604 may include fewer or more branches 702, 704, 706 in other embodiments. In this embodiment, branches 702, 704, 706 include electrical terminals 722, 724, 726 (denoted T7, T8, and T9, respectively). Electrical terminal 722 is electrically coupled between resistor 708 and fuse 716, electrical terminal 724 is electrically coupled between resistor 710 and fuse 718, and electrical terminal 726 is electrically coupled between resistor 712 and fuse 720.

In this embodiment, second circuit path 612 includes a plurality of branches 728, 730, 732 of resistors 734, 736, 738 (denoted R13, R14, and R15, respectively) and fuses 742, 744, 746 (denoted F10, F11, and F12, respectively) connected in series. Branches 728, 730, 732 are coupled in parallel between node 606 and gate 406 of solid-state switch 408. In this embodiment, branch 728 is formed by resistor 734 in series with fuse 742, branch 730 is formed by resistor 736 in series with fuse 744, and branch 732 is formed by resistor 738 in series with fuse 746. In some embodiments, resistor 740 (denoted R16) is in parallel with branches 728, 730, 732, although resistor 740 may be omitted in other embodiments. Further, second circuit path 612 may include fewer or more branches 728, 730, 732 in other embodiments. In this embodiment, branches 728, 730, 732 include electrical terminals 748, 750, 752 (denoted T10, T11, and T12, respectively). Electrical terminal 748 is electrically coupled between resistor 734 and fuse 742, electrical terminal 750 is electrically coupled between resistor 736 and fuse 744, and electrical terminal 752 is electrically coupled between resistor 738 and fuse 720. Generally, the resistance values of resistors 708, 710, 712, 714 for first circuit path 604 are independently selectable values and may be different than the resistance values of resistors 734, 736, 738, 740 of second circuit path 612.

In this embodiment, first circuit path 604 includes a diode 754 (denoted D2) having an anode electrically coupled to output 608 of gate driver 610 and a cathode electrically coupled to node 606. In some embodiments, diode 754 is reversed (as illustrated by the dashed lines).

In FIG. 7, the effective Ron is the parallel combination of branches 728, 730, 732 and resistor 740. Further, the effective Roff is the parallel combination of branches 702, 704, 706 and resistor 714 in series with the parallel combination of branches 728, 730, 732 and resistor 740. The polarity of diode 754 determines whether the effective Ron is more or less than the effective Roff.

In a production environment, fuses 716, 718, 720, 742, 744, 746 may be selectively blown using a programming current pulse applied between electrical terminal 614 and electrical terminals 722, 724, 726, 748, 750, 752. The programming current pulse may, for example be a current pulse selectively applied across fuses 716, 718, 720, 742, 744, 746 in order to selectively blow open fuses 716, 718, 720, 742, 744, 746 in order to modify the effective Ron and Roff, and consequentially, the turn-on time and turn-off time of solid-state switch 408, as previously described with respect to FIG. 5.

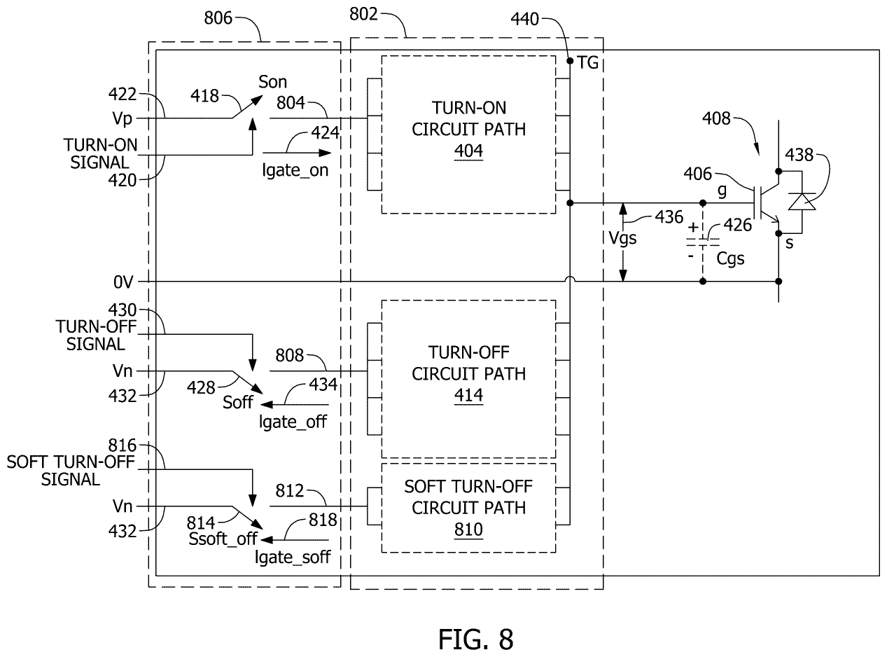

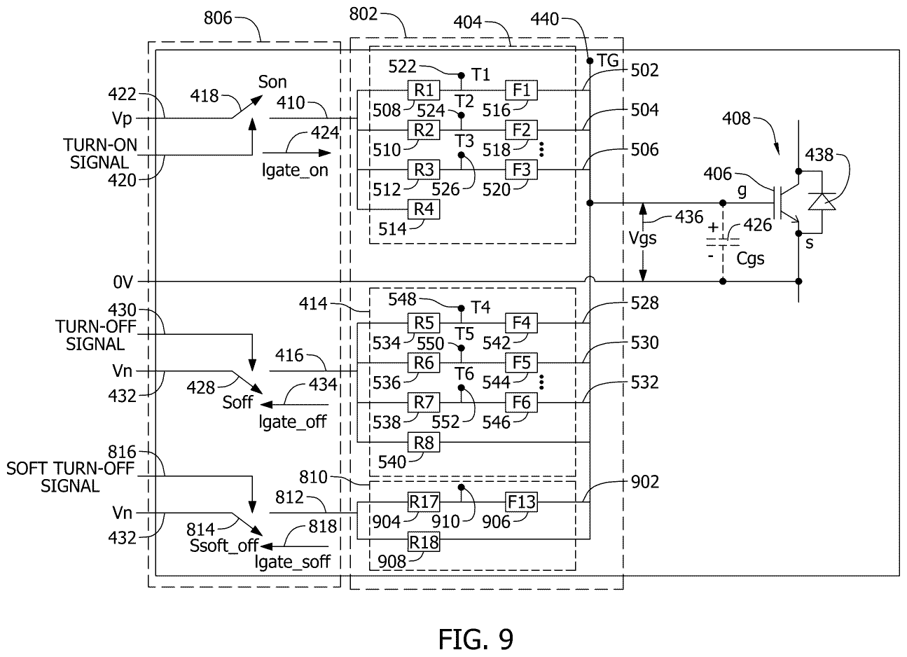

FIG. 8 depicts a gate driver circuit 802 in another exemplary embodiment. In this embodiment, gate driver circuit 802 includes turn-on circuit path 404 coupled between gate 406 of solid-state switch 408 and a first output 804 of a gate driver 806. In FIG. 8, turn-on circuit path 404 defines a turn-on time for solid-state switch 408 (e.g., turn-on circuit path 404 defines Ron for solid-state switch 408).

In this embodiment, gate driver circuit 802 further includes turn-off circuit path 414 coupled between gate 406 of solid-state switch 408 and a second output 808 of gate driver 806. In FIG. 8, turn-off circuit path 414 defines a turn-off time for solid-state switch 408 (e.g., turn-off circuit path 414 defines Roff for solid-state switch 408). In this embodiment, gate driver 806 operates similarly as previously described for gate driver 412 of FIGS. 4 and 5.

If excessive operating current through solid-state switch 408 occurs (e.g., during short circuit conditions), a soft-turn off method may be used to turn solid-state switch 408 off. Typically, the effective resistance (soft Roff) of soft turn-off circuit path 810 is five to ten times higher than the effective Roff of turn-off circuit path 414.

In this embodiment, gate driver circuit 802 further includes a soft turn-off circuit path 810 coupled between gate 406 of solid-state switch 408 and a third output 812 of gate driver 806. In FIG. 8, soft turn-off circuit path 810 defines a soft turn-off time for solid-state switch 408, where the soft turn-off time is longer than the turn-off time generated by turn-off circuit path 414. Electronic switch Ssoft_off 814, in response to receiving a soft turn-off signal 816, applies Vn 432 to gate 406 of solid-state switch 408 via the effective soft Roff associated with soft turn-off circuit path 810 to turn off solid-state switch 408 (utilizing a gate current (igate_soff) 818, which charges Cgs 426 of solid-state switch 408 towards Vn 432).

As previously described, turn-on circuit path 404 and/or turn-off circuit path 414 includes one or more branches of resistors and fuses connected in series (not shown), where the one or more branches are electrically coupled in parallel.

In this embodiment, soft turn-off circuit path 810 also includes one or more branches of resistors and fuses connected in series (not shown), where the one or more branches are electrically coupled in parallel. Thus, soft turn-off circuit path 810 may be configured to vary soft Roff and thus, the soft turn-off time, by selectively blowing open one or more fuses in soft turn-off circuit path 810.

FIG. 9 depicts gate driver circuit 802 in another exemplary embodiment. In this embodiment, soft turn-off circuit path 810 includes a branch 902 having a resistor 904 (denoted R17) in series with a fuse 906 (denoted F13) coupled between third output 812 of gate driver 806 and gate 406 of solid-state switch 408. In this embodiment, a resistor 908 (denoted R18) is in parallel with branch 902, although resistor 908 may be omitted in other embodiments. Soft turn-off circuit path 810 may include more branches 502 in other embodiments. In this embodiment, branch 902 include electrical terminal 910 (denoted T13) electrically coupled between resistor 904 and fuse 906. Electrical terminal 910 and electrical terminal 440 may be used to selectively blow open fuse 906 using a programming current pulse, similar to that previously described in order to modify soft Roff for soft turn-off circuit path 810, with the result being that the soft-turn off time for solid-state switch 408 is configurable depending on whether fuse 906 is blown open. Generally, the resistance values of resistors 904, 908 of soft turn-off circuit path 810 are independently selectable values and may be different than the resistance values of resistors 508, 510, 512, 514 for turn-on circuit path 404 and the resistance values of resistors 534, 536, 538, 540 of turn-off circuit path 414.

Further, in FIG. 9, fuses 516, 518, 520 of turn-on circuit path 404 and/or fuses 542, 544, 546 of turn-off circuit path may be selectively blown open as previously described, in order to modify the effective Ron and Roff, respectively, for gate driver circuit 802. As discussed previously, modifying the effective Ron and Roff allows the turn-on time and turn-off time, respectively, for solid-state switch 408 to be configured. Although soft turn-off circuit path 810 has been described with respect to turn-on circuit path 404 and turn-off circuit path 414 of FIGS. 4 and 5, the application of soft turn-off circuit path 810 applies equally to the embodiments described in FIGS. 6 and 7, with respect to first circuit path 604 and second circuit path 612.

The embodiments described herein provide enhanced gate driver circuits for solid-state switches that are tunable in turn-off time, turn-on time, and soft turn-off time, thereby providing technical benefits over the art. The technical benefits of the enhanced gate driver circuits described herein include, at least: (a) providing for an independent adjustment of the turn-off time, the turn-on time, and the soft turn-off time for solid-state switches; and (b) reducing the cost and complexity of driving circuits for the solid-state switches by providing a generic circuit that can be programed as needed to selectively blow fuses and modify Ron, Roff, and soft Roff.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the embodiments, including the best mode, and also to enable any person skilled in the art to practice the embodiments, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A gate driver circuit, comprising:
a turn-on circuit path coupled between a gate of a solid-state switch and a first output of a gate driver, wherein the turn-on circuit path defines a turn-on time for the solid-state switch; and
a turn-off circuit path coupled between the gate and a second output of the gate driver, wherein the turn-off circuit path defines a turn-off time for the solid-state switch,
wherein the turn-on circuit path and/or the turn-off circuit path includes one or more branches of resistors and fuses connected in series, and wherein the one or more branches are electrically coupled in parallel.

2. The gate driver circuit of claim 1, wherein:
the turn-on time and/or the turn-off time are configurable based on which of the fuses in the one or more branches are blown open, respectively, in the turn-on circuit path and the turn-off circuit path.

3. The gate driver circuit of claim 1, wherein:
the one or more branches comprise a plurality of branches.

4. The gate driver circuit of claim 1, further comprising:
electrical terminals disposed between the resistors and the fuses that are configured to selectively receive a current pulse to blow open one or more of the fuses and configure the turn-on time and/or the turn-off time.

5. The gate driver circuit of claim 1, wherein:
the turn-on circuit path and/or the turn-off circuit path includes a resistor in parallel with the one or more branches of resistors and fuses.

6. The gate driver circuit of claim 1, further comprising:
a soft turn-off circuit path coupled between the gate and a third output of the gate driver, wherein the soft turn-off circuit path defines a soft turn-off time for the solid-state switch that is more than the turn-off time.

7. The gate driver circuit of claim 6, wherein:
the soft turn-off circuit path includes one or more additional branches of resistors and fuses connected in series, and
the one or more additional branches are electrically coupled in parallel.

8. The gate driver circuit of claim 7, wherein:
the soft turn-off time is configurable based on which of the fuses in the one or more additional branches are blown open in the soft turn-off circuit path.

9. The gate driver circuit of claim 7, wherein:
the soft turn-off circuit path includes a resistor in parallel with the one or more branches of resistors and fuses.

10. The gate driver circuit of claim 7, wherein:
the one or more additional branches comprise a plurality of branches.

11. The gate driver circuit of claim 10, further comprising:
electrical terminals disposed between the resistors and fuses in the one or more additional branches that are configured to selectively receive a current pulse to blow open one or more of the fuses and configure the soft turn-off time.

12. A gate driver circuit, comprising:
a first circuit path coupled between a node and an output of a gate driver; and
a second circuit path coupled between the node and a gate of a solid-state switch,
wherein the first circuit path and/or the second circuit path includes one or more branches of resistors and fuses connected in series, and wherein the one or more branches are electrically coupled in parallel.

13. The gate driver circuit of claim 12, further comprising:
a diode coupled between the output of the gate driver and the node,
wherein an anode of the diode is electrically coupled to the output of the gate driver, and
wherein a cathode of the diode is electrically coupled to the node.

14. The gate driver circuit of claim 13, wherein:
the second circuit path defines a turn-on time for the solid-state switch, and
the first circuit path in series with the second circuit path defines a turn-off time for the solid-state switch.

15. The gate driver circuit of claim 14, wherein:
the turn-on time is configurable based on which of the fuses in the one or more branches in the second circuit path are blown open, and
the turn-off time is configurable based on which of the fuses in the one or more branches in the first circuit path and the second circuit path are blown open.

16. The gate driver circuit of claim 12, wherein:
the first circuit path and/or the second circuit path includes a resistor in parallel with the one or more branches of resistors and fuses.

17. The gate driver circuit of claim 12, further comprising:
electrical terminals disposed between the resistors and fuses that are configured to receive a current pulse to blow open one or more of the fuses.

18. A gate driver circuit, comprising:
a turn-on circuit path coupled between a gate of a solid-state switch and a first output of a gate driver,
wherein the turn-on circuit path defines a turn-on time for the solid-state switch,
wherein the turn-on circuit path includes a plurality of branches of resistors and fuses connected in series, and
wherein the turn-on time is configurable based on which of the fuses in the plurality of branches are selectively blown open.

19. The gate driver circuit of claim 18, further comprising:
electrical terminals disposed between the resistors and the fuses that are configured to receive a current pulse and blow open one or more of the fuses to configure the turn-on time.

20. The gate driver circuit of claim 18, further comprising:
a turn-off circuit path coupled between the gate and a second output of the gate driver, wherein the turn-off circuit path defines a turn-off time for the solid-state switch,
wherein the turn-off circuit path includes an additional plurality of branches of resistors and fuses connected in series, and
wherein the turn-off time is configurable based on which of the fuses in the additional plurality of branches are selectively blown open.
